(19) United States
(12) Patent Application Publication
(10) Pub. No.: US 2025/0241192 A1
(43) Pub. Date: Jul. 24, 2025

(54) DISPLAY DEVICE

(71) Applicant: Innolux Corporation, Miaoli County (TW)

(72) Inventors: Chien-Hung Wu, Miaoli County (TW); Feng-Yu Lin, Miaoli County (TW); Chiung-Chieh Kuo, Miaoli County (TW); Kuan-Hung Kuo, Miaoli County (TW)

(73) Assignee: Innolux Corporation, Miaoli County (TW)

(21) Appl. No.: 19/000,758

(22) Filed: Dec. 24, 2024

(30) Foreign Application Priority Data
Jan. 23, 2024 (CN) 202410094415.3

(51) Int. Cl. H10K 77/10; H10H 29/49; H10H 29/85; H10H 29/851; H10H 29/854; H10H 29/855; H10K 59/127; H10K 59/131; H10K 59/38; H10K 59/80; H10K 102/00

(52) U.S. Cl. CPC H10K 77/111; H10H 29/49; H10H 29/8508; H10H 29/8515; H10H 29/8517; H10H 29/854; H10H 29/855; H10K 59/127; H10K 59/131; H10K 59/38; H10K 59/8722; H10K 59/873; H10K 59/8791; H10K 2102/311; H10K 2102/351

(57) ABSTRACT

A display device is provided in the disclosure. The display device includes a first flexible substrate, a second flexible substrate, a display unit, a color conversion layer, a support layer, a first adhesive layer, a protective layer and a second adhesive layer. The second flexible substrate is disposed opposite to the first flexible substrate. The display unit is disposed between the first flexible substrate and the second flexible substrate. The color conversion layer is disposed between the second flexible substrate and the display unit. The support layer is disposed under the first flexible substrate. The first adhesive layer is disposed between the support layer and the first flexible substrate. The protective layer is disposed on the second flexible substrate. The second adhesive layer is disposed between the second flexible substrate and the protective layer.

### CROSS-REFERENCE TO RELATED APPLICATION

This application claims the priority benefit of China application serial no. 202410094415.3, filed on Jan. 23, 2024. The entirety of the above-mentioned patent application is hereby incorporated by reference herein and made a part of this specification.

### BACKGROUND

### Technical Field

The disclosure relates to a display device, and in particular relates to a display device that may improve the problem of deformation due to long-term bending or flexing or reduce the probability of damage to the display unit resulting in abnormal images.

### Description of Related Art

Electronic devices or spliced electronic devices have been widely used in various fields such as communication, display, automotive, or aviation, etc. With the vigorous development of electronic devices, the electronic devices are being developed towards thinness and lightness, which has led to higher requirements for the reliability or quality of the electronic devices.

### SUMMARY

The disclosure provides a display device that may improve the problem of deformation due to long-term bending or flexing or reduce the probability of damage to the display unit resulting in abnormal images.

The display device of the disclosure includes a first flexible substrate, a second flexible substrate, a display unit, a color conversion layer, a support layer, a first adhesive layer, a protective layer, and a second adhesive layer. The second flexible substrate is disposed opposite to the first flexible substrate. The display unit is disposed between the first flexible substrate and the second flexible substrate. The color conversion layer is disposed between the second flexible substrate and the display unit. The support layer is disposed under the first flexible substrate.

The first adhesive layer is disposed between the support layer and the first flexible substrate. The protective layer is disposed on the second flexible substrate. The second adhesive layer is disposed between the second flexible substrate and the protective layer.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1 is a cross-sectional schematic diagram of a display device of a first embodiment of the disclosure.

FIG. 2 is a cross-sectional schematic diagram of a display device of a second embodiment of the disclosure.

FIG. 3 is a cross-sectional schematic diagram of a display device of a third embodiment of the disclosure.

FIG. 4 is a cross-sectional schematic diagram of a display device of a fourth embodiment of the disclosure.

FIG. 5 is a cross-sectional schematic diagram of a display device of a fifth embodiment of the disclosure.

FIG. 6 is a cross-sectional schematic diagram of a display device of a sixth embodiment of the disclosure.

FIG. 7 is a cross-sectional schematic diagram of a display device of a seventh embodiment of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the following description and patent claims, words such as “comprising” and “including” are open-ended words, so they should be interpreted as meaning “including but not limited to . . . “.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

As used herein, the terms “about,” “approximately,” “substantially,” and “roughly” generally mean within 10%, within 5%, within 3%, within 2%, within 1%, or within 0.5% of a given value or range. The quantity given here is an approximate quantity, that is, even though “about,” “approximately,” “substantially,” and “roughly” are not specified, the meaning of “about,” “approximately,” “substantially,” and “roughly” are still implied.

In some embodiments of the disclosure, terms related to joining and connecting, such as “connected”, “interconnected”, etc., unless otherwise defined, may mean that two structures are in direct contact, or may also mean that two structures are not in direct contact, in which there are other structures located between these two structures. The terms related to joining and connecting may also include the case where both structures are movable, or both structures are fixed. Furthermore, the term “coupled” includes any direct and indirect means of electrical connection.

In some embodiments of the disclosure, optical microscopy (OM), scanning electron microscope (SEM), film thickness profiler (α-step), ellipsometer, or other suitable methods may be used to measure the area, width, thickness, or height of each element, or the distance or pitch between elements. In detail, according to some embodiments, a scanning electron microscope may be used to obtain a cross-sectional structure image including a component to be measured, and to measure the area, width, thickness, or height of each element, or the distance or pitch between elements.

In the disclosure, the electronic device may include a display device, a light-emitting device, a backlight device, a virtual reality device, an augmented reality (AR) device, an antenna device, a sensing device, a splicing device or any combination thereof, but not limited thereto. The display device may be a non-self-luminous display or a self-luminous display according to requirements, and may be a color display or a monochrome display according to requirements.

The antenna device may be a liquid crystal antenna device or a non-liquid crystal antenna device, the sensing device may be a sensing device for sensing capacitance, light, heat or ultrasonic waves, and the splicing device may be a display splicing device or an antenna splicing device, but not limited thereto. Electronic units in electronic devices may include passive and active elements, such as capacitors, resistors, inductors, diodes, transistors, etc. The diode may include a light-emitting diode (LED) or a photodiode. The light-emitting diode may include, for example, an organic light-emitting diode (OLED), a mini light-emitting diode (mini LED), a micro light-emitting diode (micro LED), or a quantum dot light-emitting diode (quantum dot LED), but not limited thereto. The transistor may include, for example, a top gate thin film transistor, a bottom gate thin film transistor, or a dual gate thin film transistor, but not limited thereto. The electronic device may also include fluorescence materials, phosphor materials, quantum dot (QD) materials, or other suitable materials according to requirements, but not limited thereto. The electronic device may have a peripheral system such as a driving system, a control system, a light source system, and the like to support a display device, an antenna device, a wearable device (e.g., including augmented reality or virtual reality devices), an in-vehicle device (e.g., including car windshields), or a splicing device. It should be noted that, the electronic device may be any arrangement and combination thereof, but not limited thereto. Hereinafter, a display device is used as an example to illustrate the disclosure, but the disclosure is not limited thereto.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

References of the exemplary embodiments of the disclosure are to be made in detail. Examples of the exemplary embodiments are illustrated in the drawings. If applicable, the same reference numerals in the drawings and the descriptions indicate the same or similar parts.

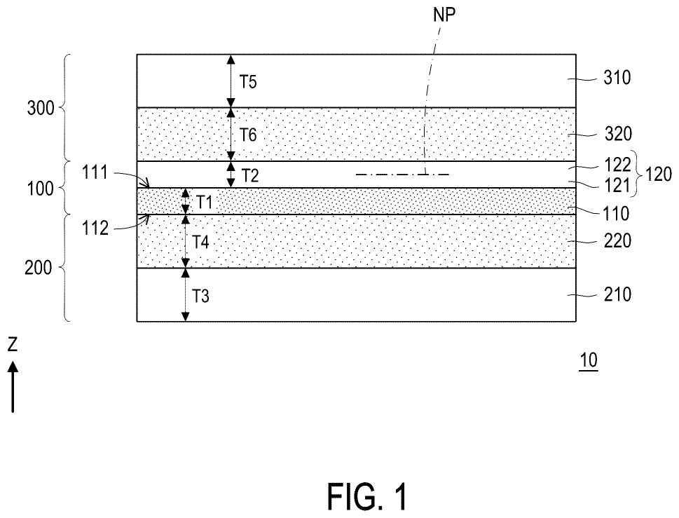

FIG. 1 is a cross-sectional schematic diagram of a display device of a first embodiment of the disclosure. Referring to FIG. 1, the display device 10 of this embodiment includes a first flexible substrate 110, a display unit 120, a support layer 210, a first adhesive layer 220, a protective layer 310, and a second adhesive layer 320. In this embodiment, the display device 10 may be a flexible display device such as a bendable or curvable display device, a foldable display device or a rollable display device, but not limited thereto. In this embodiment, the total thickness of the display device 10 may be, for example, 28 microns to 370 microns, or 33 microns to 370 microns, but not limited thereto.

In this embodiment, the combination of the first flexible substrate 110 and the display unit 120 may be regarded as the main axis 100 of the display device 10, and the combination of the support layer 210 and the first adhesive layer 220 may be regarded as first reinforced structure 200 of the display device 10, and the combination of the protective layer 310 and the second adhesive layer 320 may be regarded as the second reinforced structure 300 of the display device 10. The second reinforced structure 300 and the first reinforced structure 200 are respectively located on opposite upper and lower sides of the main axis 100. In this embodiment, the components in the second reinforced structure 300 and the components in the first reinforced structure 200 may be disposed in a symmetrical manner with the main axis 100 being regarded as an axis of symmetry, but not limited thereto.

Specifically, the first flexible substrate 110 has a first surface 111 and a second surface 112 opposite to each other. The first flexible substrate 110 has a thickness T1, and the thickness T1 may be the thickness of the first flexible substrate 110 measured along the direction Z (i.e., the normal direction of the first flexible substrate 110). In this embodiment, the thickness T1 of the first flexible substrate 110 may be, for example, 5 microns (μm) to 50 microns, but not limited thereto. In this embodiment, the first flexible substrate 110 may be a soft substrate. For example, the material of the first flexible substrate 110 may include polycarbonate (PC), polyimide (PI), polyethylene terephthalate (PET), fiber-reinforced plastic (FRP), other suitable plastic materials, or a combination thereof, but not limited thereto.

The display unit 120 is disposed on the first surface 111 of the first flexible substrate 110. The display unit 120 includes a circuit layer 121 and a light-emitting unit 122, and the light-emitting unit 122 may be electrically connected to the circuit layer 121. In this embodiment, the circuit layer 121 may include driving circuits (not shown) such as transistors, scanning lines, and data lines to drive the light-emitting unit 122 to emit light. The light-emitting unit 122 may include an organic light-emitting diode, an inorganic light-emitting diode (LED), other self-luminous units, or a combination thereof, but not limited thereto. The inorganic light-emitting diode may be, for example, a mini light-emitting diode or a micro light-emitting diode. The display unit 120 has a thickness T2, and the thickness T2 may be the thickness of the display unit 120 measured along the direction Z. In this embodiment, the thickness T2 of the display unit 120 may be, for example, 8 microns to 20 microns, but not limited thereto.

The support layer 210 is disposed under the second surface 112 of the first flexible substrate 110. The support layer 210 has a thickness T3, and the thickness T3 may be the thickness of the support layer 210 measured along the direction Z. In this embodiment, the thickness T3 of the support layer 210 may be, for example, 5 microns to 50 microns, but not limited thereto. In this embodiment, the support layer 210 may be a rigid substrate, a soft substrate, or a combination thereof. For example, the material of the support layer 210 may include metal, glass, polycarbonate, polyimide, polyethylene terephthalate, other suitable support materials, or combinations thereof, but not limited thereto.

The first adhesive layer 220 is disposed between the support layer 210 and the first flexible substrate 110. The first adhesive layer 220 may be configured to bond the support layer 210 and the first flexible substrate 110. The first adhesive layer 220 has a thickness T4, and the thickness T4 may be the thickness of the first adhesive layer 220 measured along the direction Z.

In this embodiment, the thickness T4 of the first adhesive layer 220 may be, for example, 5 microns to 100 microns, but not limited thereto. In this embodiment, the material of the first adhesive layer 220 may include thermosetting glue, UV glue, or a combination thereof. For example, the material of the first adhesive layer 220 may include optically clear adhesive (OCA), optically clear resin (OCR), pressure sensitive adhesives (PSA), other suitable adhesive materials, or a combination thereof, but not limited thereto.

The protective layer 310 is disposed on the first surface 111 of the first flexible substrate 110. The protective layer 310 has a thickness T5, and the thickness T5 may be the thickness of the protective layer 310 measured along the direction Z. In this embodiment, the thickness T5 of the protective layer 310 may be, for example, 5 microns to 50 microns, but not limited thereto. In this embodiment, the protective layer 310 may be a rigid substrate, a soft substrate, or a combination thereof. For example, the material of the protective layer 310 may include metal, glass, polycarbonate, polyimide, polyethylene terephthalate, other suitable protective materials, or combinations thereof, but not limited thereto.

The second adhesive layer 320 is disposed between the display unit 120 and the protective layer 310. The second adhesive layer 320 may be configured to bond the display unit 120 and the protective layer 310. The second adhesive layer 320 has a thickness T6, and the thickness T6 may be the thickness of the second adhesive layer 320 measured along the direction Z. In this embodiment, the thickness T6 of the second adhesive layer 320 may be, for example, 5 microns to 100 microns, but not limited thereto. In this embodiment, the material of the second adhesive layer 320 may include thermosetting glue, UV glue, or a combination thereof. For example, the material of the second adhesive layer 320 may include optically clear adhesive (OCA), optically clear resin (OCR), pressure sensitive adhesives (PSA), other suitable adhesive materials, or a combination thereof, but not limited thereto.

In this embodiment, when the display device 10 is bent, the display unit 120 may be substantially located on the neutral plane NP of the display device 10, thereby reducing the stress exerted on the display unit 120 when the display device 10 is bent. Therefore, the problem of deformation of the display device 10 due to long-term bending or flexing may be improved, and the probability of the display unit 120 being damaged (e.g., abnormal electrical connection or damaged element) resulting in abnormal images may be reduced. The “neutral plane NP” refers to the area that is least affected by stress when the display device 10 is bent. Specifically, “neutral plane NP” refers to the interface between the tensile zone and the compression zone of a structure when it is bent. The structure located at this interface (neutral plane) is neither subjected to compression nor tension. In other words, the normal stress on each point on the neutral plane is zero.

In this embodiment, the method in which the display unit 120 may be substantially located at the neutral plane NP when the display device 10 is bent may be, for example, since the components in the second reinforced structure 300 (including the protective layer 310 and the second adhesive layer 320) and the components in the first reinforced structure 200 (including the support layer 210 and the first adhesive layer 220) are symmetrically disposed with respect to the main axis 100, therefore, when the material (or physical properties) and thickness T5 of the protective layer 310 may respectively be the same or similar to the material (or physical properties) and thickness T3 of the support layer 210, and the material (or physical properties) and thickness T6 of the second adhesive layer 320 may respectively be the same or similar to the material (or physical properties) and thickness T4 of the first adhesive layer 220, the display unit 120 may be substantially located on the neutral plane NP when the display device 10 is bent, but not limited thereto. “Physical properties” may include coefficient of thermal expansion (CTE), stress and/or elongation, etc., but not limited thereto.

In some embodiments, the material (or physical properties) of the support layer may also be different from the material (or physical properties) of the protective layer, the thickness of the support layer may also be different from the thickness of the protective layer, the material (or physical properties) of the first adhesive layer may also be different from the material (or physical properties) of the second adhesive layer, and/or the thickness of the first adhesive layer may also be different from the thickness of the second adhesive layer, as long as the display unit may be substantially located on the neutral plane when the display device is bent.

In some embodiments, the main axis 100 of the display device 10 may also be provided with anti-reflective material, but not limited thereto.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

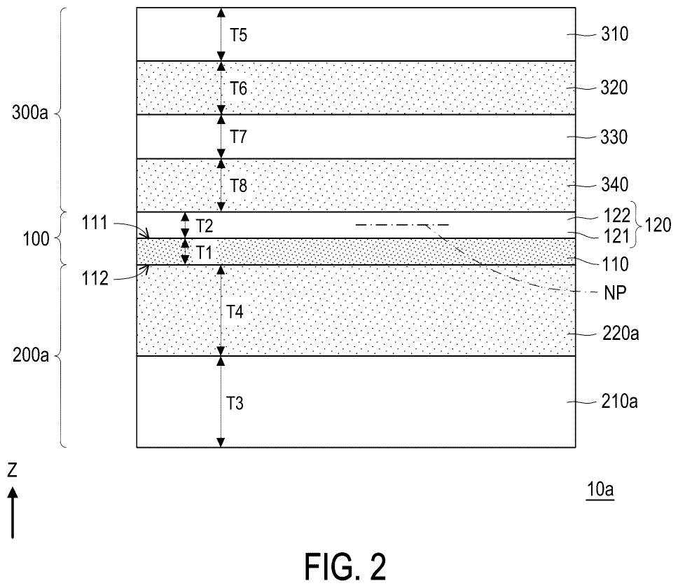

FIG. 2 is a cross-sectional schematic diagram of a display device of a second embodiment of the disclosure. Referring to FIG. 2 and FIG. 1 at the same time, the display device 10a of this embodiment is similar to the display device 10 of FIG. 1, the only differences between them are: the second reinforced structure 300a of the display device 10a of this embodiment further includes a circular polarizer 330 and a fourth adhesive layer 340, and the components in the second reinforced structure 300a and the components in the first reinforced structure 200a are disposed asymmetrically with respect to the main axis 100.

Specifically, referring to FIG. 2, the circular polarizer 330 is disposed on the first surface 111 of the first flexible substrate 110, and the circular polarizer 330 is disposed between the display unit 120 and the second adhesive layer 320. The circular polarizer 330 has a thickness T7, and the thickness T7 may be the thickness of the circular polarizer 330 measured along the direction Z. In this embodiment, the thickness T7 of the circular polarizer 330 may be, for example, 5 microns to 70 microns, but not limited thereto.

The fourth adhesive layer 340 is disposed between the display unit 120 and the circular polarizer 330. The fourth adhesive layer 340 may be configured to bond the display unit 120 and the circular polarizer 330. The fourth adhesive layer 340 has a thickness T8, and the thickness T8 may be the thickness of the fourth adhesive layer 340 measured along the direction Z. In this embodiment, the thickness T8 of the fourth adhesive layer 340 may be, for example, 5 microns to 100 microns, but not limited thereto. In this embodiment, the material of the fourth adhesive layer 340 may include thermosetting glue, UV glue, or a combination thereof. For example, the material of the fourth adhesive layer 340 may include optically clear adhesive (OCA), optically clear resin (OCR), pressure sensitive adhesives (PSA), other suitable adhesive materials, or a combination thereof, but not limited thereto.

In this embodiment, the total thickness of the display device 10a may be, for example, 42 microns to 540 microns, or 43 microns to 540 microns, but not limited thereto.

In this embodiment, when the display device 10a is bent, the display unit 120 may be substantially located on the neutral plane NP of the display device 10a, thereby reducing the stress exerted on the display unit 120 when the display device 10a is bent. Therefore, the problem of deformation of the display device 10a due to long-term bending or flexing may be improved, and the probability of the display unit 120 being damaged (e.g., abnormal electrical connection or damaged element) resulting in abnormal images may be reduced.

In this embodiment, the method in which the display unit 120 may be substantially located at the neutral plane NP when the display device 10a is bent may be, for example, since the components in the second reinforced structure 300a (including the protective layer 310, the second adhesive layer 320, the circular polarizer 330, and the fourth adhesive layer 340) and the components in the first reinforced structure 200a (including the support layer 210a and the first adhesive layer 220a) are asymmetrically disposed with respect to the main axis 100, therefore, by making the materials the same (e.g., the material of the support layer 210a and/or the first adhesive layer 220a are respectively the same as the material of the protective layer 310 and/or the second adhesive layer 320) and the thickness different (e.g., the thickness T3 of the support layer 210a and/or the thickness T4 of the first adhesive layer 220a is different from the thickness T5 of the protective layer 310 and/or the thickness T6 of the second adhesive layer 320), the display unit 120 may be substantially located at the neutral plane NP when the display device 10a is bent.

For example, when the materials (or physical properties) of the support layer 210a and the first adhesive layer 220a are respectively the same or similar to the materials (or physical properties) of the protective layer 310 and the second adhesive layer 320, by making the thickness T3 of the support layer 210a and the thickness T4 of the first adhesive layer 220a respectively greater than the thickness T5 of the protective layer 310 and the thickness T6 of the second adhesive layer 320, the display unit 120 may be substantially located at the neutral plane NP when the display device 10a is bent.

Although in this embodiment, the asymmetrically disposed display device 10a may be substantially located at the neutral plane NP when the display unit 120 bends by making the materials the same (i.e., the material of the support layer 210a and the first adhesive layer 220a are respectively the same as the material of the protective layer 310 and the second adhesive layer 320) and the thicknesses different (i.e., the thickness T3 of the support layer 210a and the thickness T4 of the first adhesive layer 220a are respectively greater than the thickness T5 of the protective layer 310 and the thickness T6 of the second adhesive layer 320), but not limited thereto. In some embodiments, the asymmetrically disposed display device may also be substantially located at the neutral plane NP when the display unit 120 bends by using different materials (e.g., the material of the support layer and/or the first adhesive layer are respectively different from the material of the protective layer and/or the second adhesive layer) and the same thickness (e.g., the thickness of the support layer and the first adhesive layer are respectively the same as the thickness of the protective layer and the second adhesive layer). In some embodiments, the asymmetrically disposed display device may also be substantially located at the neutral plane NP when the display unit 120 bends by using different materials (e.g., the material of the support layer and/or the first adhesive layer are respectively different from the material of the protective layer and/or the second adhesive layer) and different thicknesses (e.g., the thickness of the support layer and/or the first adhesive layer are respectively different from the thickness of the protective layer and/or the second adhesive layer).

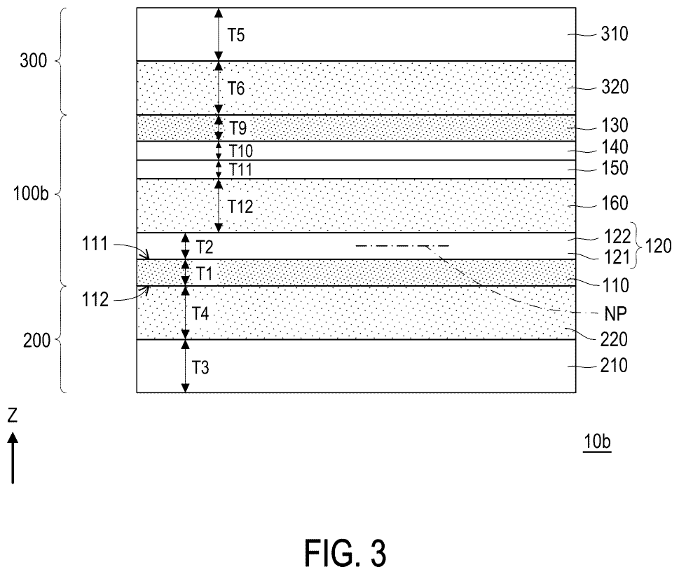

FIG. 3 is a cross-sectional schematic diagram of a display device of a third embodiment of the disclosure. Referring to FIG. 3 and FIG. 1 at the same time, the display device 10b of this embodiment is similar to the display device 10 of FIG. 1, the only differences between them are: the main axis 100b of the display device 10b of this embodiment further includes a second flexible substrate 130, a color filter layer 140, a color conversion layer 150, and a third adhesive layer 160.

Specifically, refer to FIG. 3, in the main axis 100b, the second flexible substrate 130 is disposed on the first surface 111 of the first flexible substrate 110, and the second flexible substrate 130 is disposed opposite to the first flexible substrate 110. The second flexible substrate 130 has a thickness T9, and the thickness T9 may be the thickness of the second flexible substrate 130 measured along the direction Z. In this embodiment, the thickness T9 of the second flexible substrate 130 may be, for example, 5 microns to 50 microns, but not limited thereto. In this embodiment, the second flexible substrate 130 may be a soft substrate. For example, the material of the second flexible substrate 130 may include polycarbonate, polyimide, polyethylene terephthalate, fiber-reinforced plastic, other suitable plastic materials, or a combination thereof, but not limited thereto.

The color filter layer 140 is disposed between the first flexible substrate 110 and the second flexible substrate 130, and the color filter layer 140 is disposed between the color conversion layer 150 and the second flexible substrate 130. The color filter layer 140 has a thickness T10, and the thickness T10 may be the thickness of the color filter layer 140 measured along the direction Z. In this embodiment, the color filter layer 140 may include a red filter layer, a green filter layer, a blue filter layer or other suitable color filter layers, but not limited thereto.

The color conversion layer 150 is disposed between the first flexible substrate 110 and the second flexible substrate 130, and the color conversion layer 150 is disposed between the display unit 120 and the second flexible substrate 130. The color conversion layer 150 has a thickness T11, and the thickness T11 may be the thickness of the color conversion layer 150 measured along the direction Z. In this embodiment, the sum of the thickness T10 of the color filter layer 140 and the thickness T11 of the color conversion layer 150 may be, for example, 10 microns to 20 microns, but not limited thereto. In this embodiment, the color conversion layer 150 may include quantum dots, fluorescence, phosphor, or other suitable color conversion materials, or a combination thereof, but not limited thereto.

The third adhesive layer 160 is disposed between the first flexible substrate 110 and the second flexible substrate 130, and the third adhesive layer 160 is disposed between the display unit 120 and the color conversion layer 150. The third adhesive layer 160 has a thickness T12, and the thickness T12 may be the thickness of the third adhesive layer 160 measured along the direction Z. In this embodiment, the thickness T12 of the third adhesive layer 160 may be, for example, 5 microns to 100 microns, but not limited thereto. In this embodiment, the material of the third adhesive layer 160 may include thermosetting glue, UV glue, or a combination thereof.

For example, the material of the third adhesive layer 160 may include optically clear adhesive (OCA), optically clear resin (OCR), pressure sensitive adhesives (PSA), other suitable adhesive materials, or a combination thereof, but not limited thereto.

The display unit 120 is disposed between the first flexible substrate 110 and the second flexible substrate 130, and the display unit 120 is disposed between the first flexible substrate 110 and the third adhesive layer 160.

The protective layer 310 is disposed on the second flexible substrate 130.

The second adhesive layer 320 is disposed between the second flexible substrate 130 and the protective layer 310. The second adhesive layer 320 may be configured to bond the second flexible substrate 130 and the protective layer 310.

In this embodiment, the total thickness of the display device 10b may be, for example, 53 microns to 540 microns, but not limited thereto.

In this embodiment, when the display device 10b is bent, the display unit 120 may be substantially located on the neutral plane NP of the display device 10b, thereby reducing the stress exerted on the display unit 120 when the display device 10b is bent. Therefore, the problem of deformation of the display device 10b due to long-term bending or flexing may be improved, and the probability of the display unit 120 being damaged (e.g., abnormal electrical connection or damaged element) resulting in abnormal images may be reduced.

In this embodiment, since the components in the second reinforced structure 300 (including the protective layer 310 and the second adhesive layer 320) and the components in the first reinforced structure 200 (including the support layer 210 and the first adhesive layer 220) are symmetrically disposed with respect to the main axis 100b, therefore, the manner in which the display unit 120 may be substantially located at the neutral plane NP when the display device 10b is bent may be substantially the same or similar to the display device 10 of the first embodiment in FIG. 1, and is not repeated herein.

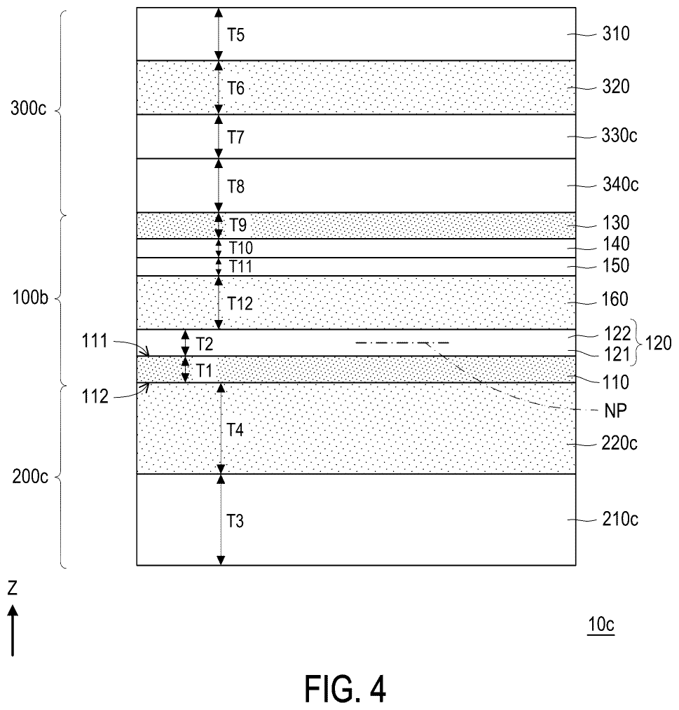

FIG. 4 is a cross-sectional schematic diagram of a display device of a fourth embodiment of the disclosure. Referring to FIG. 4 and FIG. 3 at the same time, the display device 10c of this embodiment is similar to the display device 10b of FIG. 3, the only differences between them are: the second reinforced structure 300c of the display device 10c of this embodiment further includes a circular polarizer 330c and a fourth adhesive layer 340c, and the components in the second reinforced structure 300c and the components in the first reinforced structure 200c are disposed asymmetrically with respect to the main axis 100b.

Specifically, referring to FIG. 4, the circular polarizer 330c is disposed on the first surface 111 of the first flexible substrate 110, and the circular polarizer 330c is disposed between the second flexible substrate 130 and the second adhesive layer 320. The circular polarizer 330c has a thickness T7, and the thickness T7 may be the thickness of the circular polarizer 330c measured along the direction Z. In this embodiment, the thickness T7 of the circular polarizer 330c may be, for example, 5 microns to 70 microns, but not limited thereto.

The fourth adhesive layer 340c is disposed between the second flexible substrate 130 and the circular polarizer 330c. The fourth adhesive layer 340c may be configured to bond the display unit 120 and the circular polarizer 330c. The fourth adhesive layer 340c has a thickness T8, and the thickness T8 may be the thickness of the fourth adhesive layer 340c measured along the direction Z. In this embodiment, the thickness T8 of the fourth adhesive layer 340c may be, for example, 5 microns to 100 microns, but not limited thereto. In this embodiment, the material of the fourth adhesive layer 340c may include thermosetting glue, UV glue, or a combination thereof. For example, the material of the fourth adhesive layer 340c may include optically clear adhesive (OCA), optically clear resin (OCR), pressure sensitive adhesives (PSA), other suitable adhesive materials, or a combination thereof, but not limited thereto.

In this embodiment, the total thickness of the display device 10c may be, for example, 63 microns to 710 microns, but not limited thereto.

In this embodiment, when the display device 10c is bent, the display unit 120 may be substantially located on the neutral plane NP of the display device 10c, thereby reducing the stress exerted on the display unit 120 when the display device 10c is bent. Therefore, the problem of deformation of the display device 10c due to long-term bending or flexing may be improved, and the probability of the display unit 120 being damaged (e.g., abnormal electrical connection or damaged element) resulting in abnormal images may be reduced.

In this embodiment, since the components in the second reinforced structure 300c (including the protective layer 310, the second adhesive layer 320, the circular polarizer 330c, and the fourth adhesive layer 340c) and the components in the first reinforced structure 200c (including the support layer 210c and the first adhesive layer 220c) are asymmetrically disposed with respect to the main axis 100b, therefore, the manner in which the display unit 120 may be substantially located at the neutral plane NP when the display device 10c is bent may be substantially the same or similar to the display device 10a of the second embodiment in FIG. 2, and is not repeated herein.

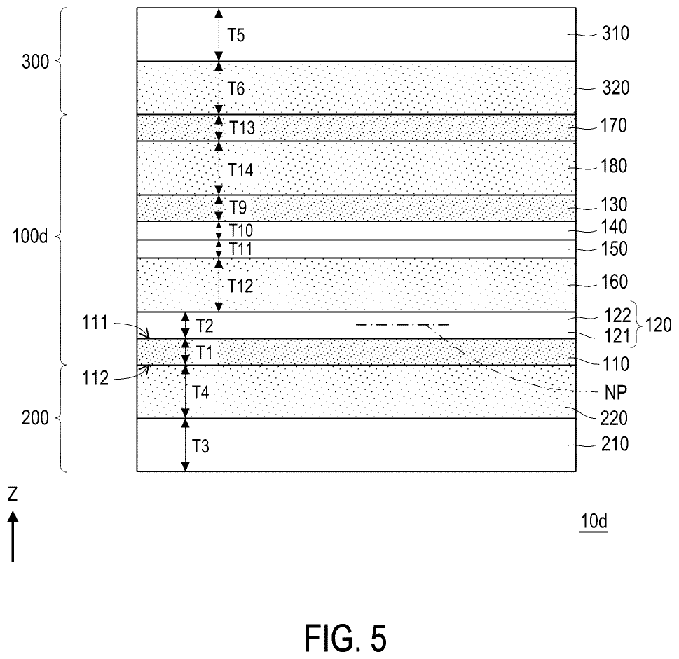

FIG. 5 is a cross-sectional schematic diagram of a display device of a fifth embodiment of the disclosure. Referring to FIG. 5 and FIG. 3 at the same time, the display device 10d of this embodiment is similar to the display device 10b of FIG. 3, the only differences between them are: the main axis 100d of the display device 10d in this embodiment further includes a third flexible substrate 170 and a fifth adhesive layer 180, thereby increasing stiffness or increasing the layout space for circuits.

Specifically, referring to FIG. 5, the third flexible substrate 170 is disposed between the second flexible substrate 130 and the second adhesive layer 320. The third flexible substrate 170 has a thickness T13, and the thickness T13 may be the thickness of the third flexible substrate 170 measured along the direction Z. In this embodiment, the thickness T13 of the third flexible substrate 170 may be, for example, 5 microns to 50 microns, but not limited thereto. In this embodiment, the third flexible substrate 170 may be a soft substrate. For example, the material of the third flexible substrate 170 may include polycarbonate, polyimide, polyethylene terephthalate, fiber-reinforced plastic, other suitable plastic materials, or a combination thereof, but not limited thereto.

The fifth adhesive layer 180 is disposed between the second flexible substrate 130 and the third flexible substrate 170. The fifth adhesive layer 180 has a thickness T14, and the thickness T14 may be the thickness of the fifth adhesive layer 180 measured along the direction Z. In this embodiment, the thickness T14 of the fifth adhesive layer 180 may be, for example, 5 microns to 100 microns, but not limited thereto. In this embodiment, the material of the fifth adhesive layer 180 may include thermosetting glue, UV glue, or a combination thereof. For example, the material of the fifth adhesive layer 180 may include optically clear adhesive (OCA), optically clear resin (OCR), pressure sensitive adhesives (PSA), other suitable adhesive materials, or a combination thereof, but not limited thereto.

In this embodiment, the total thickness of the display device 10d may be, for example, 73 microns to 860 microns, but not limited thereto.

In this embodiment, when the display device 10d is bent, the display unit 120 may be substantially located on the neutral plane NP of the display device 10d, thereby reducing the stress exerted on the display unit 120 when the display device 10d is bent. Therefore, the problem of deformation of the display device 10d due to long-term bending or flexing may be improved, and the probability of the display unit 120 being damaged (e.g., abnormal electrical connection or damaged element) resulting in abnormal images may be reduced.

In this embodiment, since the components in the second reinforced structure 300 (including the protective layer 310 and the second adhesive layer 320) and the components in the first reinforced structure 200 (including the support layer 210 and the first adhesive layer 220) are symmetrically disposed with respect to the main axis 100d, therefore, the manner in which the display unit 120 may be substantially located at the neutral plane NP when the display device 10d is bent may be substantially the same or similar to the display device 10 of the first embodiment in FIG. 1, and is not repeated herein.

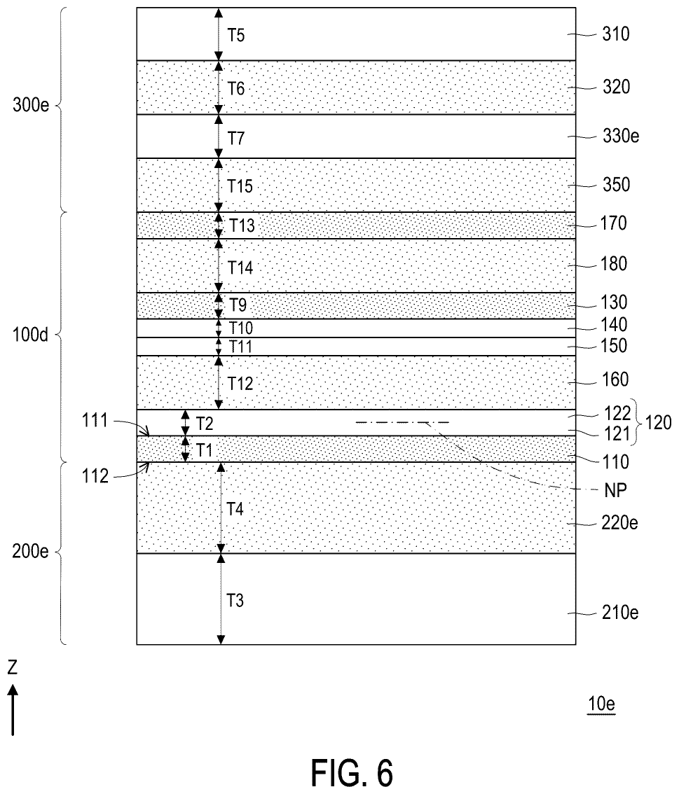

FIG. 6 is a cross-sectional schematic diagram of a display device of a sixth embodiment of the disclosure. Referring to FIG. 6 and FIG. 5 at the same time, the display device 10e of this embodiment is similar to the display device 10d of FIG. 5, the only differences between them are:

the second reinforced structure 300e of the display device 10e of this embodiment further includes a circular polarizer 330e and a sixth adhesive layer 350, and the components in the second reinforced structure 300e and the components in the first reinforced structure 200e are disposed asymmetrically with respect to the main axis 100d.

Specifically, referring to FIG. 6, the circular polarizer 330e is disposed between the third flexible substrate 170 and the second adhesive layer 320. The circular polarizer 330e has a thickness T7, and the thickness T7 may be the thickness of the circular polarizer 330e measured along the direction Z. In this embodiment, the thickness T7 of the circular polarizer 330e may be, for example, 5 microns to 70 microns, but not limited thereto.

The sixth adhesive layer 350 is disposed between the third flexible substrate 170 and the circular polarizer 330e. The sixth adhesive layer 350 may be configured to bond the third flexible substrate 170 and the circular polarizer 330e. The sixth adhesive layer 350 has a thickness T15, and the thickness T15 may be the thickness of the sixth adhesive layer 350 measured along the direction Z. In this embodiment, the thickness T15 of the sixth adhesive layer 350 may be, for example, 5 microns to 100 microns, but not limited thereto. In this embodiment, the material of the sixth adhesive layer 350 may include thermosetting glue, UV glue, or a combination thereof. For example, the material of the sixth adhesive layer 350 may include optically clear adhesive (OCA), optically clear resin (OCR), pressure sensitive adhesives (PSA), other suitable adhesive materials, or a combination thereof, but not limited thereto.

In this embodiment, the total thickness of the display device 10e may be, for example, 83 microns to 1030 microns, but not limited thereto.

In this embodiment, when the display device 10e is bent, the display unit 120 may be substantially located on the neutral plane NP of the display device 10e, thereby reducing the stress exerted on the display unit 120 when the display device 10e is bent. Therefore, the problem of deformation of the display device 10e due to long-term bending or flexing may be improved, and the probability of the display unit 120 being damaged (e.g., abnormal electrical connection or damaged element) resulting in abnormal images may be reduced.

In this embodiment, since the components in the second reinforced structure 300e (including the protective layer 310, the second adhesive layer 320, the circular polarizer 330e, and the sixth adhesive layer 350) and the components in the first reinforced structure 200e (including the support layer 210e and the first adhesive layer 220e) are asymmetrically disposed with respect to the main axis 100d, therefore, the manner in which the display unit 120 may be substantially located at the neutral plane NP when the display device 10e is bent may be substantially the same or similar to the display device 10a of the second embodiment in FIG. 2, and is not repeated herein.

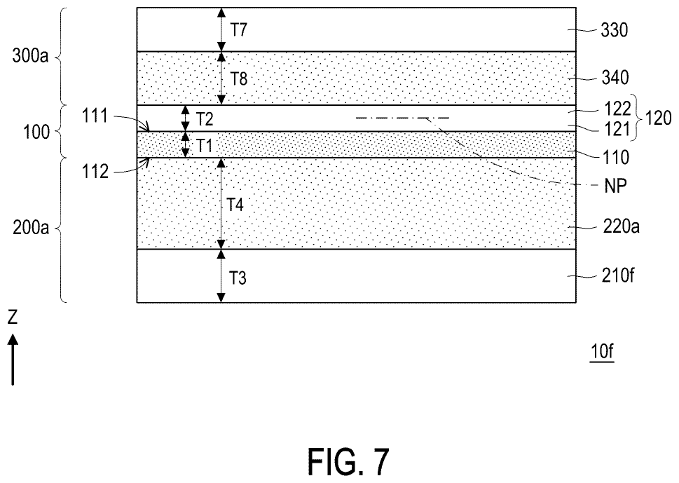

FIG. 7 is a cross-sectional schematic diagram of a display device of a seventh embodiment of the disclosure. In this embodiment, the display device 10f, which is disposed in an asymmetrical manner, may locate the display unit 120 substantially on the neutral plane NP when the display device 10f is bent by adjusting the thickness and material of each layer.

For example, the material and thickness T3 of the support layer 210f may be, for example, PET and 5 microns to 50 microns, the material and thickness T4 of the first adhesive layer 220a may be, for example, OCA and 5 microns to 100 microns, the material and thickness T1 of the first flexible substrate 110 may be, for example, PI and 5 microns to 50 microns, the thickness T2 of the display unit 120 may be, for example, 8 microns to 20 microns, the material and thickness T8 of the fourth adhesive layer 340 may be, for example, OCA and 5 microns to 100 microns, and the thickness T7 of the circular polarizer 330 may be, for example, 5 microns to 70 microns.

To sum up, in the display device according to the embodiment of the present disclosure, the display unit is designed to be substantially located on the neutral plane of the display device when the display device is bent, thereby reducing the stress exerted on the display unit when the display device is bent. Therefore, the problem of deformation of the display device due to long-term bending or flexing may be improved, and the probability of the display unit being damaged (e.g., abnormal electrical connection or damaged element) resulting in abnormal images may be reduced. In addition, by the design of disposing a third flexible substrate in the main axis, the stiffness may be increased or the layout space for circuits may be increased.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. A display device, comprising:
a first flexible substrate;
a second flexible substrate, disposed opposite to the first flexible substrate;
a display unit, disposed between the first flexible substrate and the second flexible substrate;
a color conversion layer, disposed between the display unit and the second flexible substrate;
a support layer, disposed under the first flexible substrate;
a first adhesive layer, disposed between the support layer and the first flexible substrate;
a protective layer, disposed on the second flexible substrate; and
a second adhesive layer, disposed between the second flexible substrate and the protective layer.

2. The display device according to claim 1, wherein when the display device is bent, the display unit is located on a neutral plane of the display device.

3. The display device according to claim 1, wherein the display unit comprises a circuit layer and a light-emitting unit, and the light-emitting unit is electrically connected to the circuit layer.

4. The display device according to claim 1, wherein a material of the support layer is the same as a material of the protective layer, and a thickness of the support layer is the same as a thickness of the protective layer.

5. The display device according to claim 1, wherein a material of the first adhesive layer is the same as a material of the second adhesive layer, and a thickness of the first adhesive layer is the same as a thickness of the second adhesive layer.

6. The display device according to claim 1, further comprising:
a third adhesive layer, disposed between the display unit and the color conversion layer.

7. The display device according to claim 1, further comprising:
a color filter layer, disposed between the color conversion layer and the second flexible substrate.

8. The display device according to claim 1, further comprising:
a circular polarizer, disposed between the second flexible substrate and the second adhesive layer.

9. The display device according to claim 8, further comprising:
a fourth adhesive layer, disposed between the second flexible substrate and the circular polarizer.

10. The display device according to claim 9, wherein a material of the support layer is the same as a material of the protective layer, and a thickness of the support layer is greater than a thickness of the protective layer.

11. The display device according to claim 9, wherein a material of the first adhesive layer is the same as a material of the second adhesive layer, and a thickness of the first adhesive layer is greater than a thickness of the second adhesive layer.

12. The display device according to claim 9, wherein a material of the support layer is different from a material of the protective layer, and a thickness of the support layer is greater than a thickness of the protective layer.

13. The display device according to claim 1, further comprising:
a third flexible substrate, disposed between the second flexible substrate and the second adhesive layer.

14. The display device according to claim 13, further comprising:
a fifth adhesive layer, disposed between the second flexible substrate and the third flexible substrate.

15. The display device according to claim 14, wherein a material of the support layer is the same as a material of the protective layer, and a thickness of the support layer is the same as a thickness of the protective layer.

16. The display device according to claim 14, wherein a material of the first adhesive layer is the same as a material of the second adhesive layer, and a thickness of the first adhesive layer is the same as a thickness of the second adhesive layer.

17. The display device according to claim 13, further comprising:
a circular polarizer, disposed between the third flexible substrate and the second adhesive layer.

18. The display device according to claim 17, further comprising:
a sixth adhesive layer, disposed between the third flexible substrate and the circular polarizer.

19. The display device according to claim 18, wherein a material of the support layer is the same as a material of the protective layer, and a thickness of the support layer is greater than a thickness of the protective layer.

20. The display device according to claim 18, wherein a material of the first adhesive layer is the same as a material of the second adhesive layer, and a thickness of the first adhesive layer is greater than a thickness of the second adhesive layer.
